(19) United States
(12) Patent Application Publication
(10) Pub. No.: US 2006/0059401 A1
(43) Pub. Date: Mar. 16, 2006

(54) Design of rate-compatible LDPC codes using optimal extending

(76) Inventor: Young Jo Ko, Daejeon (KR)

Correspondence Address: LADAS & PARRY LLP, 224 SOUTH MICHIGAN AVENUE, SUITE 1600, CHICAGO, IL, 60604, US

(21) Appl. No.: 11/201,017

(22) Filed: Aug. 10, 2005

(30) Foreign Application Priority Data
Sep. 12, 2004 (KR) 2004-103690

(51) Int. Cl. H03M 13/00

(52) U.S. Cl. 714/752

(57) ABSTRACT

Provided is a technique of encoding and decoding an LDPC code having a plurality of code rate using a single codec in a wired and wireless communication channel coding, and a method of designing a rate compatible low density parity check (LDPC) code including a step of successively adding new parity bits to variable nodes of the mother code to obtain the rate compatible code. The code with a high code rate is used as a reference code and a plurality of low-rate codes are obtained using an optimal extending technique. Using the proposed method, a single codec including a plurality of low code rate codes may be designed, maintaining an optimal performance.

### CROSS-REFERENCE TO RELATED APPLICATION

This application claims priority to and the benefit of Korean Patent Application No. 2004-103690, filed Dec. 9, 2004, the disclosure of which is incorporated herein by reference in its entirety.

### BACKGROUND

1. Field of the Invention

The present invention relates to a channel coding method of detecting and correcting errors of data in a wired/wireless communication system and, more particularly, to a method of designing a parity check matrix to allow optimal performance to be implemented and to allow a low density parity check (LDPC) code used as a channel code to have a plurality of code rates.

2. Discussion of Related Art

In recent years, high attention is paid to a low density parity check (LDPC) code. A design of a random LDPC code is generally as follows. According to Richardson et al, density evolution is used to find optimized degree distributions of infinite length LDPC codes. A finite length parity check matrix is generated using the optimized degree distribution.

The LDPC code first proposed by Gallager has been forgotten for a long time, however as interest in Turbo codes and so on increases, it was rediscovered by Mackay and Neal, who also showed that it can achieve the channel capacity. Details of the code are described in “R. G. Gallager, Low density parity check codes, MIT Press, Cambridge, Mass., 1963.”, and “D. J. C. MacKay and R. M. Neal, Near Shannon limit performance of low density parity check codes, Electron. Lett., vol. 33, no. 6, pp. 457-458, March 1997.”

In particular, Richardson et al have proposed a density evolution method for analyzing performance of regular and irregular LDPC codes with infinite block lengths, which allows optimization of LPDC codes. This is described in detail in “T. J. Richardson, M. A. Shokrollahi, and R. L. Urbanke, Design of Capacity-Approaching Irregular Low-Density Parity-Check Codes, IEEE Trans. Inform. Theory, vol. 47, pp. 619-637, February, 2001.”

The density evolution describes the average performance of an LDPC code ensemble with a given degree distribution for variable nodes and check nodes. In terms of the parity check matrix, the density evolution checks the average performance of the code ensemble, which consists of infinite number of parity check matrices. The parity-check matrices have the specified numbers of ‘1’'s in each row and each column designated by a given degree distribution, but, they are distinguished from each other with different positions of 1's.

A method of code concatenation is used to generate a rate compatible code and the code is designed using density evolution to obtain an optimal concatenated structure. Rate compatible codes can adopt the code rate with varying channel environments. For example, a linear code C1 (k′, k) of a high code rate for error detection and a linear code C2 (n, k′) as a rate compatible code for error correction are used in Type-II Hybrid ARQ. In the first transmission of packet, it is coded with a high code rate. When a nonacknowledgement (NAK) signal with respect to the transmitted packet is received, only additional parity bits not overlapping with parity bits which were previously sent are transmitted. That is an additional parity portions P1, P2, P3, . . . PL each corresponding to a code rate R1, P2, . . . , and PL are sent successively until the acknowledgement (ACK) signal is received. At each stage of transmission and reception, the receiver combines the information bits and all the parity bits received up to the current stage and performs decoding.

In order to use such an information transmission scheme, the encoders should be capable of generating codewords corresponding to a plurality of code rates, and decoders be capable of decoding the corresponding codewords. From the point of hardware implementation, making separate encoder and decoder corresponding to each code rate causes great complexity and thus, it is desirable that the plurality of code rates is accommodated in a single pair of encoder and decoder while minimizing performance degradation.

### SUMMARY OF THE INVENTION

The present invention is directed to a method of designing a rate compatible LDPC code to meet the above-described requirements. As such, the purpose of the present invention is to provide a method of designing a rate compatible LDPC code using optimal extending.

One aspect of the present invention is to provide a method of designing a rate compatible low density parity check (LDPC) code, which includes analyzing a channel capacity using density evolution equations derived with equations 6 and 7 below when the rate compatible code is constituted by regular codes having different degrees from each other.

Another aspect of the present invention is to provide a method of designing a rate compatible low density parity check (LDPC) code, which includes: analyzing a channel capacity using density evolution equations derived with equations 19 and 21 below when the rate compatible code is constituted by irregular codes having different degree distributions from each other.

The method may further include sequentially adding a new parity to a variable node of a mother code to obtain the rate compatible code having a structure such as a parity check matrix.

In addition, the method may further include sequentially obtaining a degree distribution of each edge of the parity sequentially added to the mother code using the density evolution equations.

### BRIEF DESCRIPTION OF THE DRAWINGS

The above and other features and advantages of the present invention will become more apparent to those of ordinary skill in the art by describing in detail preferred embodiments thereof with reference to the attached drawings in which:

FIG. 1 is a view illustrating a parity check matrix of a rate compatible code according to a first embodiment of the present invention;

FIG. 2 is a view illustrating a bipartite graph of the parity check matrix of FIG. 1;

FIG. 3 is a view illustrating a parity check matrix of two concatenated regular codes according to a second embodiment of the present invention;

FIG. 4 is a view illustrating a bipartite graph of the parity check matrix corresponding to FIG. 3;

FIG. 5 is a view illustrating an example of message transmission from an information node of FIG. 4 to a check node;

FIG. 6 is a view illustrating another example of message transmission from an information node of FIG. 4 to a check node;

FIG. 7 is a view illustrating an example of message transmission from a parity node of FIG. 4 to a check node;

FIG. 8 is a view illustrating another example of message transmission from a parity node of FIG. 4 to a check node;

FIG. 9 is a view illustrating an example of message transmission from a check node of FIG. 4 to a variable node; and

FIG. 10 is a view illustrating another example of message transmission from a check node of FIG. 4 to a variable node.

### DETAILED DESCRIPTION OF PREFERRED EMBODIMENTS

The present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure is thorough and complete and fully conveys the scope of the invention to those skilled in the art.

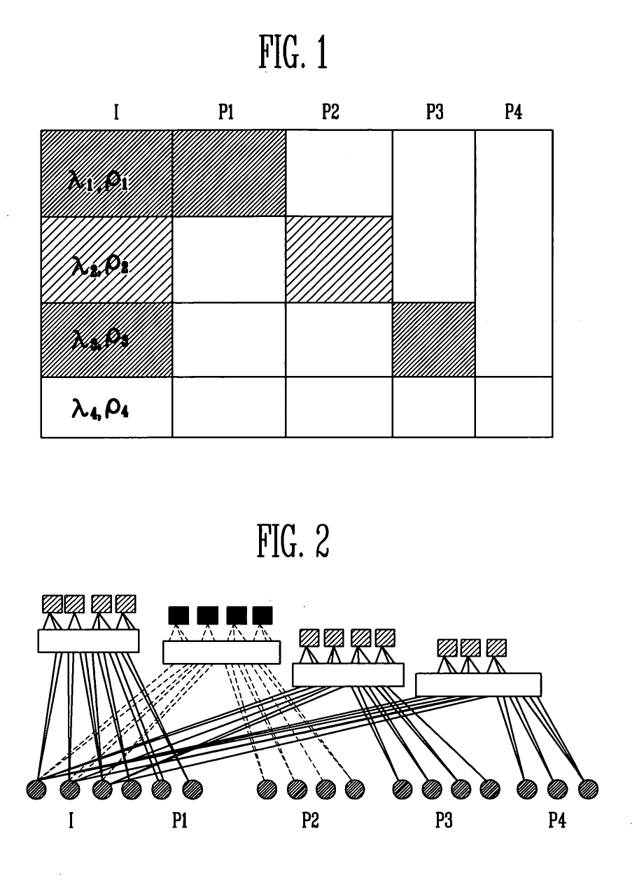

A parity check matrix which may be employed for a code suitable for the type II Hybrid ARQ as described in the discussion of the related art is shown in FIG. 1. FIG. 1 is a view illustrating a parity check matrix of a rate compatible code, and FIG. 2 is a view illustrating a bipartite graph of the parity check matrix of FIG. 1. Referring to FIG. 1, empty regions indicate regions to be filled with ‘0’.

The parity check matrix corresponding to FIG. 1 may be expressed as bipartite graphs as shown in FIG. 2. In FIG. 2, a plurality of upper small rectangular boxes indicates check nodes, a plurality of lower circles indicate variable nodes, and lines between the check nodes and the variable nodes indicate edges. Boxes on the edges indicate random permutation of the information nodes of the two codes being connected therebetween. And check nodes and variable nodes are connected to each other with a plurality of types of edge. Four edge types are present in FIG. 2.

To detail this, new parities P2, P3, and P4 are sequentially added to variable nodes I and P1 of a mother node for the rate compatibility. Types of the corresponding edges are referred to as type 1, type 2, type 3, and type 4.

An optimal extending method in the above-described configuration will be described as follows.

Degree optimization for type 1 edge: it corresponds to the mother code and uses density evolution to obtain the optimal degree distribution.

Degree optimization for type 2 edges: the degree distribution of the type 2 edges is optimized with the degree distributions for the type 1 edges fixed to be the degree distribution obtained from the cases of the type 1 edges. In this case, the above-described density evolution method is used.

Degree optimization for type 3 edges: the degree distribution of the type 3 edge is optimized with the degree distributions for the type 1 and type 2 edges fixed to be the degree distribution obtained from the cases of the type 2 edges. In this case, the above-described density evolution method is used.

Degree optimization for type 4 edge: the same method as the case of the type 3 edge is used to perform optimization.

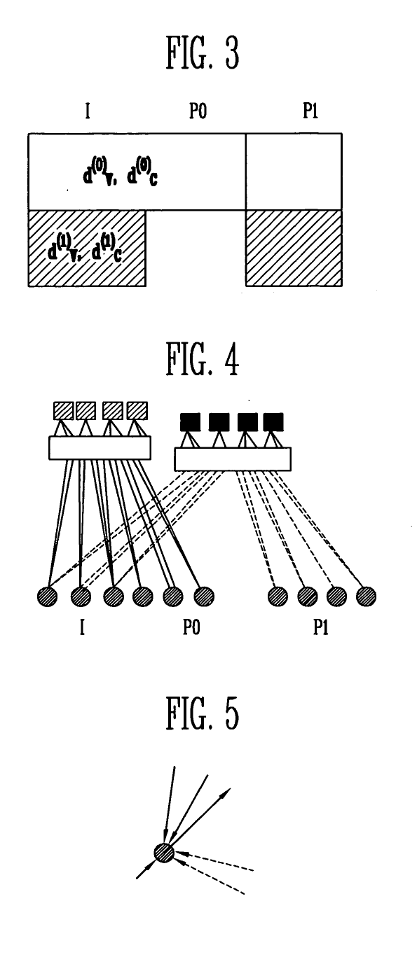

Next, a decoding method is as follows. The decoding is sequentially performed on each variable node form. Such decoding may include a serial decoding method and a parallel decoding method of simultaneously performing the decoding. In the present invention, the density evolution is applied to the parallel decoding method. Such a density evolution technique will be described in detail with reference to FIGS. 3 to 10. The density evolution technique described below is for the sake of multi-edge type LDPC codes.

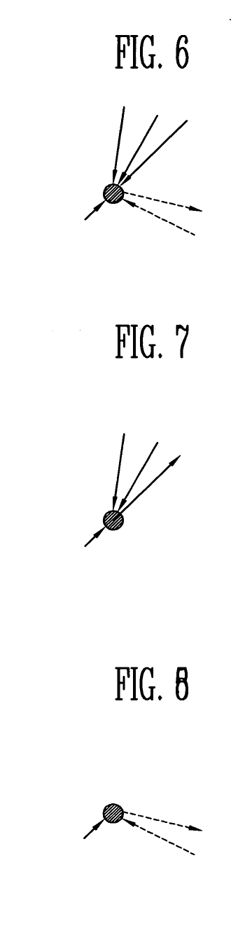

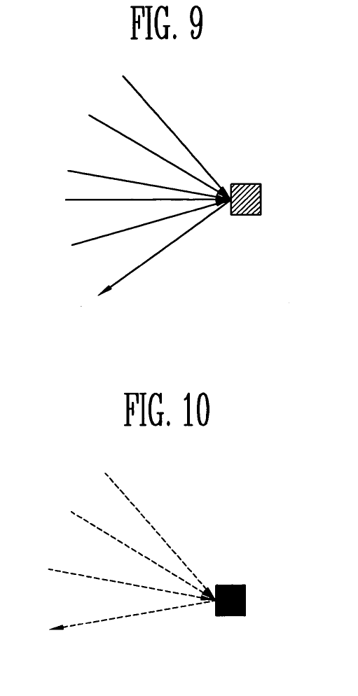

FIG. 3 is a view illustrating a parity check matrix of two concatenated regular codes, and FIG. 4 is a view illustrating a bipartite graph of the parity check matrix corresponding to FIG. 3. FIG. 5 is a view illustrating an example of message transmission from an information node to a check node, and FIG. 6 is a view illustrating another example of message transmission from an information node to a check node. FIG. 7 is a view illustrating an example of message transmission from a parity node to a check node, and FIG. 8 is a view illustrating another example of message transmission from a parity node to a check node. And FIG. 9 is a view illustrating an example of message transmission from a check node to a variable node, and FIG. 10 is a view illustrating another example of message transmission from a check node to a variable node.

1. Case of Concatenation of Two Regular Codes

FIG. 4 shows a bipartite graph corresponding to the parity check matrix of FIG. 3. There are two edge types in FIG. 4. The probability density function of a log likelihood ratio (LLR) message which is delivered via an edge per edge type is considered. That is, the probability density function of a message delivered from the variable node to the check node via the edge of type 0 is referred to as Pv⁽⁰⁾, and the probability density function delivered from the check node to the variable node is referred to as Pc⁽⁰⁾. Similarly, probability density functions corresponding to the case of the edge of type 1 are referred to as Pv⁽¹⁾, and Pc⁽¹⁾.

There are three types of nodes based on the number and kind of the edge connected to the variable node as shown in FIGS. 5 to 7. These are respectively called an information node, a parity 0 node, and a parity 1 node. Statistical handling for the message delivery becomes different depending on the kind of the edge delivering the message and the type of the variable node. For example, as shown in FIG. 5, in the case of the message delivered from the information node to the check node via the edge of type 0 at the first iteration, the probability density function corresponds to the following equation 1.
P_{ν,I}^{(0),l}=Pₒ(\textcircled{X}^{d}^{_{ν}}^{⁽⁰⁾}⁻¹P_{c}^{(0),l-1})(\textcircled{X}^{d}^{_{ν}}^{⁽¹⁾}P_{c}^{(1),l-1}) Equation 1
where, P⁰ indicates the probability density function of a channel output value, Pc^{(i),1} indicates the probability density function of a message delivered from the check node to the variable node via the i^{th} type edge at the l-th iteration, and \textcircled{X} indicates convolution.

As shown in FIG. 6, the probability density function of the message delivered from the information node to the check node via the edge of type 1 corresponds to the following equation 2.
P_{ν,I}^{(1),l}=Pₒ(\textcircled{X}^{d}^{_{ν}}^{⁽⁰⁾}P_{c}^{(0),l-1})(\textcircled{X}^{d}^{_{ν}}^{⁽¹⁾}P_{c}^{(1),l-1}) Equation 2

As shown in FIG. 7, the probability density function of the message delivered from the parity 0 node to the check node via the edge of type 0 corresponds to the following equation 3.
P_{ν,P}^{(0),l}=Pₒ\textcircled{X}^{d}^{_{ν}}^{⁽⁰⁾}⁻¹P_{c}^{(0),l-1} Equation 3

As shown in FIG. 8, the probability density function of the message delivered from the parity 1 node to the check node via the edge of type 1 corresponds to the following equation 4.
P_{ν,P}^{(1),l}=Pₒ\textcircled{X}^{d}^{_{ν}}^{⁽⁰⁾}⁻¹P_{c}^{(1),l-1} Equation 4

Pᵥ⁽⁰⁾ is comprise of two contributions one by edges of type 0 belonging to the information node and the other by edges of type 0 belonging to the parity node. When each fraction of these edges is λ_{I}⁽⁰⁾ and λ_{P}⁽⁰⁾, the following equation 5 is obtained.
P_{ν}⁽⁰⁾=λ_{I}⁽⁰⁾P_{ν,I}⁽⁰⁾+λ_{P}⁽⁰⁾P_{ν,P}⁽⁰⁾ Equation 5

Similarly, when the fractions of edges of type 1 belonging to the information node and edges of type 1 belonging to the parity node are λ₁⁽¹⁾ and λ_{P}⁽¹⁾, the following equation 6 is obtained.
P_{ν}⁽¹⁾=λ_{I}⁽¹⁾P_{ν,I}⁽¹⁾+λ_{P}⁽¹⁾P_{ν,P}⁽¹⁾ Equation 6

As shown in the bipartite graph of FIGS. 9 and 10, the message update of the check node and the probability density function of the message are carried out for each edge type. That is, the probability density function as the following equation 7 is obtained.
P_{c}^{(1),l}=ƒ(P_{ν}^{(1),l-1},d_{c}⁽¹⁾) Equation 7

2. Case of Concatenation of Two Irregular Codes

The type of the variable node is more varied compared to the case of regular codes. The variable code is distinguished by the type and degree of concatenated edge. That is, the degree of the variable node is expressed as vectors instead of the typical LDPC ensemble. That is, the degree of the node with the degree of type 0 d₀ and the degree of type 1 d₁ may be expressed as the following equation 8.
\overline{d}=(d₀,d₁) Equation 8

When the fraction of the variable node with the degree \overline{d} among the total variable nodes is ^{ν}\overline{d}, the probability density of the LLR message delivered via the edge of type 0 from the variable node having the degree \overline{d} corresponds to the following equation 9.
Pₒ(\textcircled{X}^{d}^{ₒ}⁻¹P_{c}^{(0),l-1})(\textcircled{X}^{d}^{₁}P_{c}^{(1),l-1}) Equation 9

Total number of the type 0 edge corresponds to the equation 10 below, and the fraction of the edge belonging to the degree \overline{d} corresponds to the equation 11 below.

$$n {\sum }_{\overline{d}} {v}_{\overline{d}} {d}_{0} \qquad Equation 10$$

where, n indicates the total number of the variable nodes.

$${v}_{\overline{d}} {d}_{0} / {\sum }_{\overline{d}}^{} {v}_{\overline{d}} {d}_{0} \qquad Equation 11$$

Accordingly, the probability density function of the LLR message which is averaged with respect to the type 0 edge corresponds to the following equation 12.

$${P}_{v}^{( 0 ) , l} = [ {\sum }_{\overline{d}}^{} ( {v}_{\overline{d}} {d}_{0} ) {P}_{0} ( {⊗}^{{d}_{0} - 1} {P}_{c}^{( 0 ) , l - 1} ) ( {⊗}^{{d}_{1}} {P}_{c}^{( 1 ) , l - 1} ) ] / [ {\sum }_{\overline{{d}^{′}}} {v}_{\overline{{d}^{′}}} {{d}^{′}}_{0} ] \qquad Equation 12$$

When the above-described degree distribution is expressed as a polynomial, the following equation 13 is obtained.

$$v ( {x}_{0} , {x}_{1} ) = {\sum }_{\overline{d} = ( {d}_{0} , {d}_{1} )}^{} {v}_{\overline{d}} {x}_{0}^{{d}_{0}} {x}_{1}^{{d}_{1}} \qquad Equation 13$$

where, the left side of the equation 13 is defined as is done in the equation 14 below, the right side of the equation 13 is obtained as the following equation 15.

$$\begin{matrix}v ( {x}_{0} , {x}_{1} ) = \frac{d}{{dx}_{i}} v ( {x}_{0} , {x}_{1} ) & Equation 14 \\ {\sum }_{\overline{{d}^{′}}}^{} {v}_{\overline{{d}^{′}}} {d}_{0}^{′} = {v}_{{x}_{0}} ( 1 , 1 ) & \text{Equation} 15\end{matrix}$$

Accordingly, the probability density function of the LLR message may correspond to the following equation 16.
P_{ν}^{(0),l}=Pₒνₓ_{₀}(P_{c}^{(0),l-1},P_{c}^{(1)l-1})/νₓ_{ₒ}(1,1) Equation 16

Similarly, the probability density function of the LLR message delivered via the type 1 edge from the variable nodes having the degree \overline{d} may be expressed as the following equations 17, 18, and 19.

$$\begin{matrix}{P}_{0} ( {⊗}^{{d}_{0}} {P}_{c}^{( 0 ) , l - 1} ) ( {⊗}^{{d}_{1} - 1} {P}_{c}^{( 1 ) , l - 1} ) & Equation 17 \\ {P}_{v}^{( 1 ) , l} = [ {\sum }_{\overline{d}} ( {v}_{\overline{d}} {d}_{1} ) {P}_{0} ( {⊗}^{{d}_{0}} {P}_{c}^{( 0 ) , l - 1} ) ( {⊗}^{{d}_{1} - 1} {P}_{c}^{( 1 ) , l - 1} ) ] / [ {\sum }_{\overline{{d}^{′}}} {v}_{\overline{{d}^{′}}} {d}_{1}^{′} ] & \text{Equation} 18 \\ {P}_{v}^{( 1 ) , l} = {P}_{0} {v}_{{x}_{1}} ( {P}_{c}^{( 0 ) , l - 1} , {P}_{c}^{( 1 ) l - 1} ) / {v}_{{x}_{1}} ( 1 , 1 ) & \text{Equation} 19\end{matrix}$$

The message update of the check node is performed for each edge type in the bipartite graph shown in FIG. 2. That is, the probability density function is obtained as the following equations 20 and 21.
P_{c}^{(0),l}=ƒ(P_{ν}^{(0),l-1},d_{c}⁽⁰⁾) Equation 20
P_{c}^{(1),l}=ƒ(Pᵥ^{(1),l-1},d_{c}⁽¹⁾) Equation 21

As such, the density evolution for the concatenation of more than two irregular codes may be readily obtained as an extension of the concatenation of two irregular codes.

It should be appreciated to those skilled in the art that each step of the method of designing the rate compatible LDPC code may be performed by calculating device such as a computer, a digital signal processor (DSP) or the like, and each step of the design method may be executed by a computer program without departing from the spirit and scope of the present invention.

As mentioned above, the present invention provides a parity check matrix form for designing the rate compatible LDPC code suitable for the type II Hybrid ARQ. In this case, when additional parity bits are added to a given code, these bits are defined as edges of new type and then are concatenated to the existing variable node. Such a code becomes one special case of multi-edge type LDPC codes. The rate compatible code is generated from the initial mother code with a high code rate using the extending technique, and an optimal degree distribution may be obtained at each step of extension by employing the density evolution technique described above. Then, using the obtained degree distribution, the parity check matrix corresponding to a specific size can be made.

Although exemplary embodiments of the present invention have been described with reference to the attached drawings, the present invention is not limited to these embodiments, and it should be appreciated to those skilled in the art that a variety of modifications and changes can be made without departing from the spirit and scope of the present invention.

What is claimed is:

1. A method of designing a rate compatible low density parity check (LDPC) code, comprising:
analyzing a channel capacity using density evolution equations derived with equations 22 and 23 below when the rate compatible code is constituted by regular codes having different degrees from each other:
P_{ν}⁽¹⁾=λ_{I}⁽¹⁾P_{ν,I}⁽¹⁾+λ_{P}⁽¹⁾P_{ν,P}⁽¹⁾ equation 22
P_{c}^{(1),l}=ƒ(P_{ν}^{(1),l-1},d_{c}⁽¹⁾) equation 23

2. The method as claimed in claim 1, further comprising:
sequentially adding a new parity to a variable node of a mother code to obtain the rate compatible code having a structure such as a parity check matrix.

3. The method as claimed in claim 2, further comprising:
sequentially obtaining a degree distribution of each edge of the parity sequentially added to the mother code using the density evolution equations.

4. A method of designing a rate compatible low density parity check (LDPC) code, comprising:
analyzing a channel capacity using density evolution equations derived with equations 24 and 25 below when the rate compatible code is constituted by irregular codes having different degrees distributions from each other:
P_{ν}^{(1),l}=P₀νₓ_{₁}(P_{c}^{(0),l-1},P_{c}^{(1)l-1})/νₓ_{₁}(1,1) equation 24
P_{c}^{(1),l}=ƒ(P_{ν}^{(1),l-1},d_{c}⁽¹⁾) equation 25

5. The method as claimed in claim 4, further comprising:
sequentially adding a new parity to a variable node of a mother code to obtain the rate compatible code having a structure such as a parity check matrix.

6. The method as claimed in claim 5, further comprising:
sequentially obtaining a degree distribution of each edge of the parity sequentially added to the mother code using the density evolution equations.
